(19) United States
(12) Patent Application Publication
(10) Pub. No.: US 2026/0064218 A1
(43) Pub. Date: Mar. 5, 2026

(54) Display Device

(71) Applicant: LG Display Co., Ltd., Seoul (KR)

(72) Inventors: Hyangmyoung Gwon, Paju-si (KR); JiHyun Jung, Paju-si (KR); JaeGyun Lee, Paju-si (KR); Ruda Rhe, Paju-si (KR)

(21) Appl. No.: 19/261,348

(22) Filed: Jul. 7, 2025

(30) Foreign Application Priority Data
Aug. 28, 2024 (KR) 10-2024-0116041

(51) Int. Cl. G06F 3/041; G06F 3/044; H10K 59/40; H10K 59/80

(52) U.S. Cl. CPC G06F 3/04164; G06F 3/0412; G06F 3/0446; H10K 59/40; H10K 59/873; G06F 2203/04111

(57) ABSTRACT

A display device is disclosed that may reduce the bezel area of the display device by including a plurality of light emitting elements disposed on a substrate, an encapsulation layer disposed on the plurality of light emitting elements, and a plurality of touch routing lines disposed in an inclined area of the encapsulation layer.

### CROSS-REFERENCE TO RELATED APPLICATION

This application claims priority from Republic of Korea Patent Application No. 10-2024-0116041, filed on Aug. 28, 2024, which is hereby incorporated by reference in its entirety.

### BACKGROUND

### Field

Embodiments of the disclosure relate to a display device.

### Description of Related Art

As the information society develops, demand for display devices for displaying images is increasing in various forms. Various display devices, such as liquid crystal display devices and organic light emitting display devices, are being utilized in recent years.

The display device may include a display panel and driving circuits for driving the display panel.

The display panel may include a display area where an image is displayed, and a non-display area where components such as lines for driving the display area are disposed.

The non-display area may be disposed outside the display area. The non-display area may be defined as a bezel area.

### SUMMARY

As display devices have advanced, their bezel areas have continued to shrink. However, there remains a need to further reduce the bezel area.

Embodiments of the disclosure may reduce the bezel area of the display device by providing a novel display device structure.

Embodiments of the disclosure may reduce the bezel area of the display device by newly designing a space in which touch routing lines may be disposed.

Embodiments of the disclosure may reduce the bezel area of the display device by newly designing a space in which the ground metal may be disposed.

Embodiments of the disclosure may provide a lightweight display device by reducing the bezel area.

Embodiments of the disclosure may provide a display device comprising a substrate including a display area and a non-display area outside the display area, the non-display area including a pad area and a bending area, a plurality of light emitting elements disposed on the substrate, an encapsulation layer disposed on the plurality of light emitting elements, and a plurality of touch routing lines disposed on an inclined area of the encapsulation layer.

Embodiments of the disclosure may provide a display device comprising a substrate, a plurality of light emitting elements disposed on the substrate, an encapsulation layer disposed on the plurality of light emitting elements and including a planar area and an inclined area outside the planar area, an inner touch routing line disposed in the planar area, and an outer touch routing line disposed in the inclined area.

According to embodiments of the disclosure, it is possible to reduce the bezel area of the display device by providing a novel display device structure.

According to embodiments of the disclosure, it is possible to reduce the bezel area of the display device by newly designing a space in which touch routing lines may be disposed.

According to embodiments of the disclosure, it is possible to reduce the bezel area of the display device by newly designing a space in which the ground metal may be disposed.

According to embodiments of the disclosure, it is possible to provide a lightweight display device by reducing the bezel area.

### DESCRIPTION OF DRAWINGS

FIG. 1 is a view illustrating a configuration of a display device according to embodiments of the disclosure;

FIG. 2 is a view illustrating a display panel according to an embodiment of the disclosure;

FIG. 3 is a view illustrating a substrate of a display panel according to embodiments of the disclosure;

FIG. 4 is a cross-sectional view illustrating a display area of a display panel according to embodiments of the disclosure;

FIG. 5 is a view illustrating components for touch sensing according to embodiments of the disclosure;

FIG. 6 is a view illustrating a touch routing line of a non-display area according to embodiments of the disclosure;

FIGS. 7, 8, 9, and 10 are cross-sectional views of area A-B of FIG. 6 according to embodiments of the disclosure;

FIG. 11 is a cross-sectional view of area C-D of FIG. 6 according to embodiments of the disclosure; and

FIGS. 12, 13, and 14 are cross-sectional views of area E-F of FIG. 6 according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

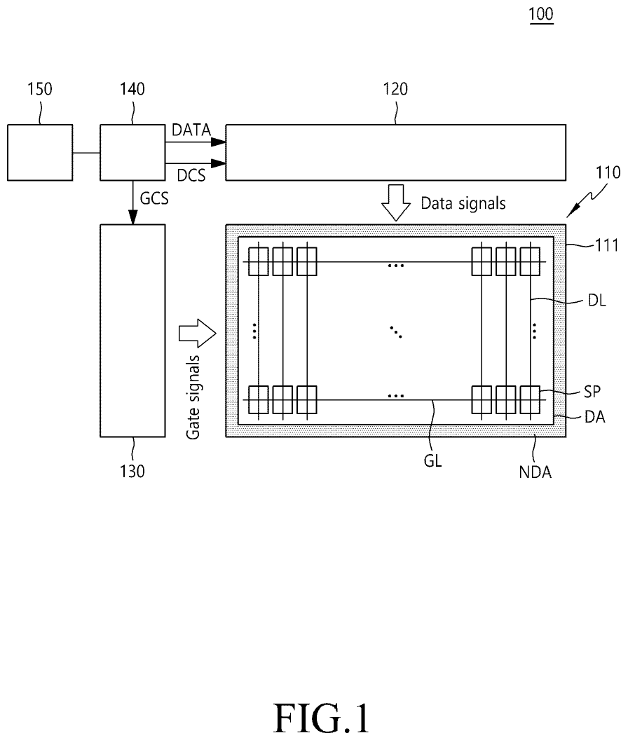

FIG. 1 is a view illustrating a system configuration of a display device 100 according to embodiments of the disclosure.

Referring to FIG. 1, a display device 100 according to embodiments of the disclosure may include a display panel 110 and display driving circuits, as components for displaying images. The display driving circuits are circuits for driving the display panel 110 and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA positioned outside the display area DA.

A plurality of subpixels SP for image displaying may be disposed in the display area DA, and the non-display area NDA may include a pad area PA positioned in a first direction from the display area DA.

In the display panel 110 according to embodiments of the disclosure, the non-display area NDA may be very small. In the disclosure, the non-display area NDA is also referred to as a “bezel.”

For example, the non-display area NDA may include a first non-display area positioned outside the display area DA in a first direction, a second non-display area positioned outside the display area DA in a second direction crossing the first direction, a third non-display area positioned outside the display area DA in a direction opposite to the first direction, and a fourth non-display area positioned outside the display area DA in a direction opposite to the second direction. One or two of the first to fourth non-display areas may include a pad area where the data driving circuit 120 is connected or bonded. Two or three of the first to fourth non-display areas where the pad area is not included may be very small.

As another example, the boundary area between the display area DA and the non-display area NDA may be bent so that the non-display area NDA may be positioned under the display area. In this case, no or little change may be made to the non-display area NDA shown to the user when the user views the display area 100 from the front.

Various types of signal lines for driving a plurality of subpixels SP may be disposed on the substrate 111 of the display panel 110.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed to extend in the first direction. Each of the plurality of gate lines GL may be disposed to extend in the second direction. Here, the first direction may be a column direction and the second direction may be a row direction. The first direction may be the row direction, and the second direction may be the column direction. For convenience of description, described below is an example in which each of the plurality of data lines DL is disposed in the column direction, and each of the plurality of gate lines GL is disposed in the row direction.

The data driving circuit 120 is a circuit for driving the plurality of data lines DL and may out data signals to the plurality of data lines DL.

The data driving circuit 120 may receive digital image data DATA from the display controller 140 and may convert the received image data DATA into analog data signals and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The data driving circuit 120 may be connected to one side (e.g., an upper or lower side) of the display panel 110. In contrast, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but alternatively, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to embodiments of the disclosure, the gate driving circuit 130 may be embedded, in a gate in panel (GIP) type, in the display panel 110. When the gate driving circuit 130 is of the gate in panel type, the gate driving circuit 130 may be formed on the substrate 111 of the display panel 110 during the manufacturing process of the display panel 110.

In the display device 100 according to embodiments of the disclosure, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA).

In the disclosure, the gate driving circuit 130 embedded in the display panel 110 in a gate-in-panel type may also be referred to as a “gate-in-panel circuit.”

The display controller 140 is a device for controlling the data driving circuit 120 and the gate driving circuit 130 and may control driving timings for the plurality of data lines DL and driving timings for the plurality of gate lines GL.

The display controller 140 may supply a data driving control signal DCS to the data driving circuit 120 to control the data driving circuit 120 and may supply a gate driving control signal GCS to the gate driving circuit 130 to control the gate driving circuit 130.

The display controller 140 may receive input image data from the host system 150 and supply image data DATA to the data driving circuit 120 based on the input image data.

The display controller 140 may be implemented as a separate component from the data driving circuit 120 or the display controller 140 and the data driving circuit 120 may be integrated into an integrated circuit (IC).

The display controller 140 may be a timing controller used in typical display technology, a control device that may perform other control functions as well as the functions of the timing controller, or a control device other than the timing controller, or may be a circuit in the control device. The display controller 140 may be implemented as various circuits or electronic components, such as an integrated circuit (IC), a field programmable gate array (FPGA), an application specific integrated circuit (ASIC), or a processor.

The display controller 140 may be mounted on a printed circuit board or a flexible printed circuit and may be electrically connected with the data driving circuit 120 and the gate driving circuit 130 through the printed circuit board or the flexible printed circuit.

The display controller 140 may transmit/receive signals to/from the data driving circuit 120 according to one or more predetermined interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit that drives and senses the touch sensor and generates and outputs touch sensing data and a touch controller that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate, together with signal lines and electrodes related to display driving, during the manufacturing process of the display panel 110.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

The display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays.

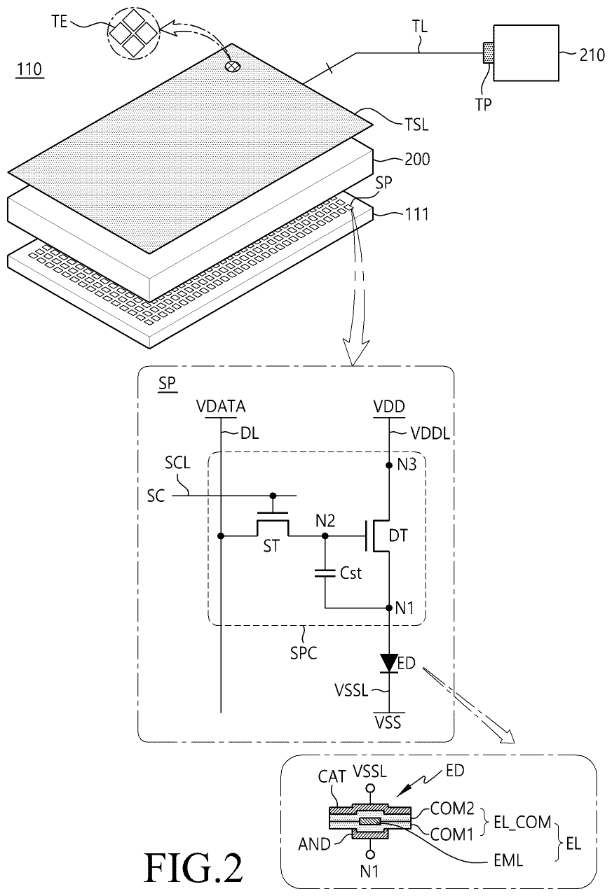

FIG. 2 is a view illustrating a display panel 110 according to an embodiment of the disclosure.

Referring to FIG. 2, the display panel 110 may include a substrate 111 disposed in a plurality of subpixels SP and an encapsulation layer 200 on the substrate 111. Here, the encapsulation layer 200 may also be referred to as an encapsulation substrate or an encapsulation portion.

Referring to FIG. 2, when the display device 100 according to embodiments of the disclosure is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of pixel driving transistors and at least one capacitor for driving the light emitting element ED. In the disclosure, the subpixel circuit SPC may drive the light emitting element ED by supplying a driving current to the light emitting element ED at a predetermined timing. The light emitting element ED may be driven by a driving current to emit light.

The plurality of pixel driving transistors may include a driving transistor DT for driving the light emitting element ED and a scan transistor ST that is turned on or off according to the scan signal SC.

The driving transistor DT may supply a driving current to the light emitting element ED.

The scan transistor ST may be configured to control the electrical state of a corresponding node in the subpixel circuit SPC or to control the state or operation of the driving transistor DT.

The at least one capacitor may include a storage capacitor Cst for maintaining a constant voltage during a frame.

To drive the subpixel SP, a data signal VDATA as an image signal and a scan signal SC as a gate signal may be applied to the subpixel SP. Further, for driving the subpixel SP, a common pixel driving voltage including the driving voltage VDD and the base voltage VSS may be applied to the subpixel SP.

The light emitting element ED may include an anode AND, a light emitting element intermediate layer EL, and a cathode CAT. The light emitting element intermediate layer EL may be disposed between the anode AND and the cathode CAT.

When the light emitting element ED is an organic light emitting element, the light emitting element intermediate layer EL may include a light emitting layer EML, a first common intermediate layer COM1 between the anode AND and the light emitting layer EML, and a second common intermediate layer COM2 between the light emitting layer EML and the cathode. The light emitting layer EML may be disposed for each subpixel SP. In contrast, the first common intermediate layer COM1 and the second common intermediate layer COM2 may be commonly disposed over a plurality of subpixels SP. The light emitting layer EML may be disposed for each light emitting area, and the first common intermediate layer COM1 and the second common intermediate layer COM2 may be commonly disposed over the plurality of light emitting areas and the non-light emitting area. The first common intermediate layer COM1 and the second common intermediate layer COM2 may be collectively referred to as a common intermediate layer EL_COM.

For example, the first common intermediate layer COM1 may include a hole injection layer HIL and a hole transport layer HTL. The second common intermediate layer COM2 may include an electron transport layer ETL and an electron injection layer EIL. The hole injection layer may inject holes from the anode AND to the hole transport layer, the hole transport layer may transport the holes to the light emitting layer EML, the electron injection layer may inject electrons from the cathode CAT to the electron transport layer, and the electron transport layer may transport electrons to the light emitting layer EML.

For example, the cathode CAT may be electrically connected to the base voltage line VSSL. The base voltage VSS, which is one type of the common pixel driving voltage, may be applied to the cathode CAT through the base voltage line VSSL. The anode AND may be electrically connected to the first node N1 of the driving transistor DT of each subpixel SP. In the disclosure, “the base voltage VSS” may also be referred to as a “base voltage VSS”, and “the base voltage line VSSL” may also be referred to as a “base voltage line VSSL”.

For example, the anode AND may be a pixel electrode disposed in each subpixel SP, and the cathode CAT may be a common electrode commonly disposed in a plurality of subpixels SP. As another example, the cathode CAT may be a pixel electrode disposed in each subpixel SP, and the anode AND may be a common electrode commonly disposed in a plurality of subpixels SP. Hereinafter, for convenience of description, it is assumed that the anode AND is a pixel electrode and the cathode CAT is a common electrode.

Each light emitting element ED may include portions in which the anode AND, the light emitting element intermediate layer EL, and the cathode CAT overlap each other. A predetermined light emitting area may be formed by each light emitting element ED. For example, the emission area of each light emitting element ED may include an area in which the anode AND, the light emitting element intermediate layer EL, and the cathode CAT overlap.

For example, the light emitting element ED may be an organic light emitting diode (OLED), an inorganic light emitting diode (LED), or a quantum dot light emitting element. For example, when the light emitting element ED is an organic light emitting diode (OLED), the light emitting element intermediate layer EL of the light emitting element ED may include a light emitting element intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node N1 electrically connected to the light emitting element ED, a second node N2 to which the data signal VDATA may be applied, and a third node N3 to which the driving voltage VDD is applied from the driving voltage line DVL.

In the driving transistor DT, the second node N2 may be a gate node, the first node N1 may be a source node or a drain node, and the third node N3 may be a drain node or a source node. Hereinafter, for convenience of description, in the driving transistor DT, the second node N2 may be a gate node, the first node N1 may be a source node, and the third node N3 may be a drain node.

The scan transistor ST included in the subpixel circuit SPC illustrated in FIG. 2 may be a switching transistor for transferring the data signal VDATA, which is an image signal, to the second node N2, which is the gate node of the driving transistor DT.

The scan transistor ST may be controlled to be turned on and off by the scan signal SC, which is a gate signal applied through the scan line SCL, which is a type of the gate line GL, to control electrical connection between the second node N2 of the driving transistor DT and the data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. In contrast, when the display panel 110 has a bottom emission structure, the subpixel circuit SPC may not overlap the light emitting element ED in the vertical direction.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors.

For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor.

Depending on the structure of the subpixel circuit SPC, the type and number of gate lines or the gate signals supplied to the subpixel SP may vary.

Further, the type and the number of common pixel driving voltages supplied to the subpixel SP may vary according to the structure of the subpixel circuit SPC.

Since the circuit elements (especially the light emitting element ED implemented as an organic light emitting diode (OLED) including an organic material) in each subpixel SP are vulnerable to external moisture or oxygen, the encapsulation layer 200 for preventing external moisture or oxygen from penetrating into the circuit elements (especially the light emitting element ED) may be disposed on the display panel 110. The encapsulation layer 200 may be configured in various forms so that the light emitting elements ED do not contact moisture or oxygen.

Referring to FIG. 2, the display device 100 according to embodiments of the disclosure may further include a touch sensor layer TSL including a plurality of sensor electrodes and a touch sensing circuit TSL configured to sense the plurality of sensor electrodes to determine the presence or absence of a touch or the coordinates of a touch.

The touch sensor layer TSL may be embedded in the display panel 110. For example, the touch sensor layer TSL may be disposed on the encapsulation layer 200 in the display panel 110.

The display panel 110 may include not only the touch sensor layer TSL, but also a plurality of touch pads where the touch sensing circuit TSL is electrically connected, and a plurality of touch routing wires TL for electrically connecting the plurality of sensor electrodes included in the touch sensor layer TSL and the plurality of touch pads where the touch sensing circuit TSL is connected.

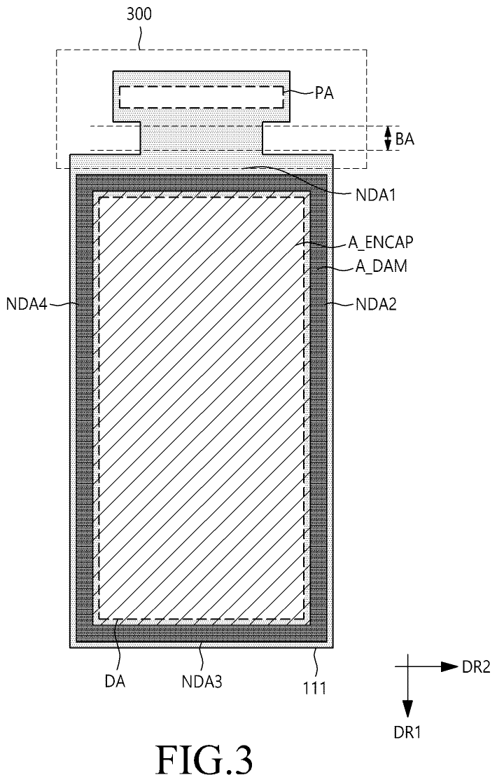

FIG. 3 illustrates a substrate 111 of a display panel 110 according to embodiments of the disclosure.

Referring to FIG. 3, the substrate 111 of the display panel 110 according to embodiments of the disclosure may include a display area DA in which an image may be displayed and a non-display area NDA in which an image is not displayed.

Referring to FIG. 3, the non-display area NDA may include a first non-display area NDA1 positioned in the first direction from the display area DA, a second non-display area NDA2 positioned in the second direction from the display area DA, a third non-display area NDA3 positioned in a direction opposite to the first direction from the display area DA, and a fourth non-display area NDA4 positioned in a direction opposite to the second direction from the display area DA. For example, the first direction may be a column direction (Y-axis direction), and the second direction crossing the first direction may be a row direction (X-axis direction).

Referring to FIG. 3, the first non-display area NDA1 may include a pad area PA in which a plurality of pads are disposed.

In the pad area PA, a plurality of pads where the driving circuit is electrically connected may be disposed. A plurality of driving circuits or printed circuit boards may be electrically connected. For example, the plurality of pads may include a plurality of display pads and a plurality of touch pads. A plurality of data lines DL, a driving voltage line VDDL and a base voltage line VSSL may be electrically connected to the plurality of pads illustrated in FIG. 3. A plurality of touch routing lines TL may be electrically connected to the plurality of touch pads.

Referring to FIG. 3, the first non-display area NDA1 may further include a bending area BA. In this case, the substrate 111 may be a flexible substrate. In some cases, the first non-display area NDA1 may not include the bending area BA.

Referring to FIG. 3, the display panel 110 may further include a ground line disposed in the non-display area NDA of the substrate 111. The ground line may be disposed from one point of the pad area PA to another point of the pad area PA via the second non-display area NDA2, the third non-display area NDA3, and the fourth non-display area NDA4.

Referring to FIG. 3, the display panel 110 may include an encapsulation layer area A_ENCAP and a dam area A_DAM.

Referring to FIG. 3, the encapsulation layer area A_ENCAP may be an area where the encapsulation layer 200 is disposed. In the display panel 110 according to embodiments of the disclosure, the encapsulation layer 200 may have a structure in which an inorganic film and an organic film are stacked. In this case, an edge of the encapsulation layer 200 may be regarded as an edge of the organic film.

Referring to FIG. 3, the dam area A_DAM may be an area surrounding the encapsulation layer area A_ENCAP. A structure functioning as a dam may be positioned in the dam area A_DAM. The dam may prevent the liquid organic film from flowing out.

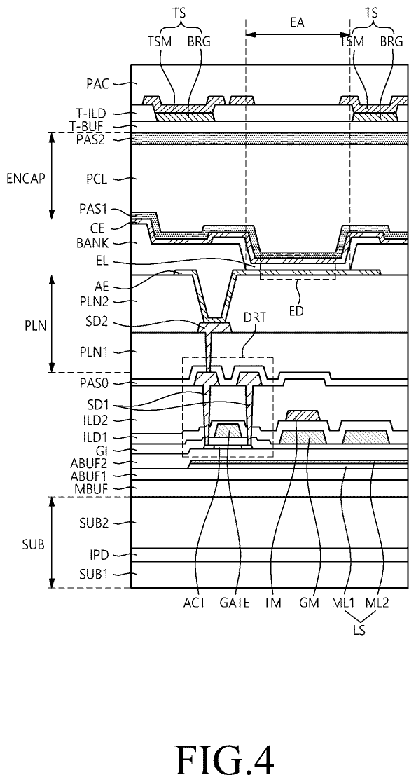

FIG. 4 is a cross-sectional view illustrating a portion of a display area DA of a display panel 110 according to embodiments of the disclosure.

Referring to FIG. 4, the substrate SUB may include a first substrate SUB1, an interlayer insulation film IPD, and a second substrate SUB2. The interlayer insulation film IPD may be positioned between the first substrate SUB1 and the second substrate SUB2. By configuring the substrate SUB with the first substrate SUB1, the interlayer insulation film IPD and the second substrate SUB2, it is possible to prevent or at least reduce moisture penetration. For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Referring to FIG. 4, on the substrate SUB, various patterns ACT, SD1, and GATE1 for forming a transistor, such as a driving transistor DRT, various insulation films MBUF, ABUF1, ABUF2, GI, ILD1, ILD2, and PAS0, and various metal patterns TM, GM, ML1, and ML2 may be disposed.

Referring to FIG. 4, a multi-buffer layer MBUF may be disposed on the second substrate SUB2. A first active buffer layer ABUF1 may be disposed on the multi-buffer layer MBUF.

A first metal layer ML1 and a second metal layer ML2 may be disposed on the first active buffer layer ABUF1. The first metal layer ML1 and the second metal layer ML2 may be a light shield layer LS for shielding light.

A second active buffer layer ABUF2 may be disposed on the first metal layer ML1 and the second metal layer ML2. An active layer ACT of the driving transistor DRT may be disposed on the second active buffer layer ABUF2.

Agate insulation film GI may be disposed while covering the active layer ACT.

A first gate electrode GATE1 of the driving transistor DRT may be disposed on the gate insulation film GI. In this case, at a position different from the position where the driving transistor DRT is formed, a gate material layer GM, together with the first gate electrode GATE1 of the driving transistor DRT, may be disposed on the gate insulation film GI.

The first interlayer insulation film ILD1 may be disposed while covering the first gate electrode GATE1 and the gate material layer GM. A metal pattern TM may be disposed on the first inter-layer insulation film ILD1. The metal pattern TM may be located in a position different from the position where the driving transistor DRT is formed. The second inter-layer insulation film TLD2 may be disposed while covering the metal pattern TM on the first inter-layer insulation film ILD1.

Two first source-drain electrode patterns SD1 may be disposed on the second interlayer insulation film TLD2. One of the two first source-drain electrode patterns SD1 is the source node of the driving transistor DRT, and the other is the drain node of the driving transistor DRT. The two first source-drain electrode patterns SD1 may be electrically connected with the two opposite sides of the active layer ACT through the contact hole of the second inter-layer insulation film ILD2, the first inter-layer insulation film ILD1, and the gate insulation film GI.

A portion of the active layer ACT overlapping the first gate electrode GATE1 is a channel area. One of the two first source-drain electrode patterns SD1 may be connected to one side of the channel area in the active layer ACT, and the other one of the two first source-drain electrode patterns SD1 may be connected to the other side of the channel area in the active layer ACT.

A passivation layer PAS0 is disposed while covering the two first source-drain electrode patterns SD1. A planarization layer PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected with one of the two first source-drain electrode patterns SD1 (corresponding to the second node N2 of the driving transistor DRT in the subpixel SP of FIG. 3) through the contact hole of the first planarization layer PLN1.

The second planarization layer PLN2 may be disposed while covering the second source-drain electrode pattern SD2. Alight emitting element ED may be disposed on the second planarization layer PLN2.

In the stacked structure of the light emitting element ED, the anode electrode AE may be disposed on the second planarization layer PLN2. The anode electrode AE may be electrically connected to the second source-drain electrode pattern SD2 through the contact hole of the second planarization layer PLN2.

The bank BANK may be disposed while covering a portion of the anode electrode AE. A portion of the bank BANK corresponding to the light emitting area EA of the subpixel SP may be opened.

A portion of the anode electrode AE may be exposed through an opening (open portion) of the bank BANK. A light emitting layer EL may be positioned on a side surface of the bank BANK and the opening (open portion) of the bank BANK. The whole or part of the light emitting layer EL may be positioned between adjacent banks BANK.

In the opening of the bank BANK, the light emitting layer EL may contact the anode electrode AE. A cathode electrode CE may be disposed on the light emitting layer EL.

The light emitting element ED may be formed by the anode electrode AE, the light emitting layer EL, and the cathode electrode CE. The light emitting layer EL may include an organic film.

An encapsulation layer ENCAP may be disposed on the above-described light emitting element ED.

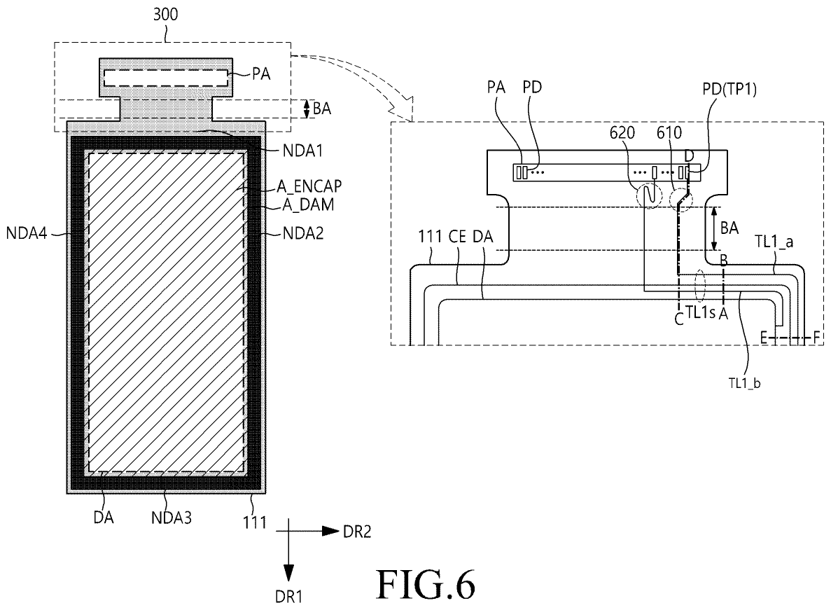

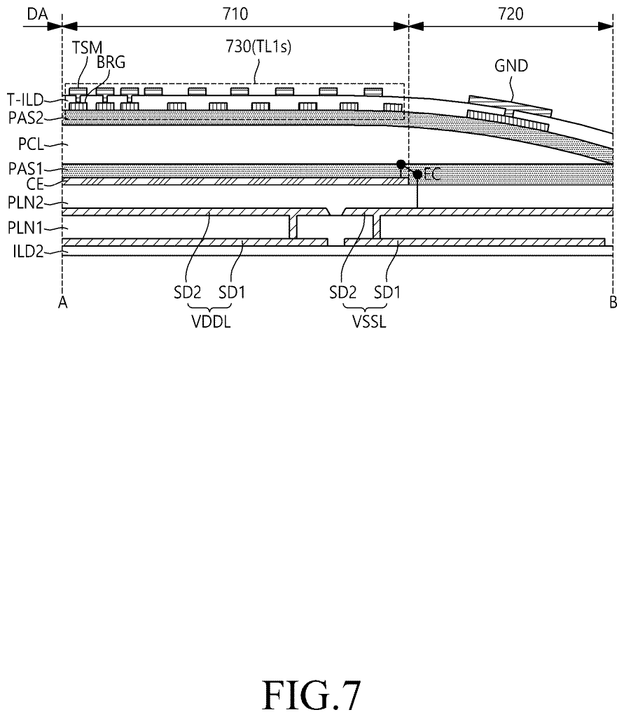

The encapsulation layer ENCAP may have a single-layer structure or a multi-layer structure. For example, as illustrated in FIG. 6 and FIG. 7, the encapsulation layer ENCAP may include a first inorganic encapsulation layer PAS1, an organic encapsulation layer PCL, and a second inorganic encapsulation layer PAS2.

For example, the first inorganic encapsulation layer PAS1 and the second inorganic encapsulation layer PAS2 may be inorganic films, and the organic encapsulation layer PCL may be an organic film. Among the first inorganic encapsulation layer PAS1, the organic encapsulation layer PCL, and the second encapsulation layer PAS2, the organic encapsulation layer PCL may be the thickest and serve as a planarization layer.

The first inorganic encapsulation layer PAS1 may be disposed on the cathode electrode CE and be disposed closest to the light emitting element ED. The first inorganic encapsulation layer PAS1 may be formed of an inorganic insulating material capable of low-temperature deposition. For example, the first inorganic encapsulation layer PAS1 may be formed of silicon nitride (SiNx), silicon oxide (SiOx), silicon oxynitride (SiON), or aluminum oxide (Al2O3). Since the first inorganic encapsulation layer PAS1 is deposited in a low temperature atmosphere, the first inorganic encapsulation layer PAS1 may prevent damage to the light emitting layer EL including an organic material vulnerable to a high temperature atmosphere during the deposition process.

The organic encapsulation layer PCL may be formed in a smaller area than the first inorganic encapsulation layer PAS1. In this case, the organic encapsulation layer PCL may be formed to expose two opposite ends of the first inorganic encapsulation layer PAS1. The organic encapsulation layer PCL serves as a buffer for relieving stress between layers due to bending of the display device 100 and may also serve to enhance planarization performance. For example, the organic encapsulation layer PCL may be an acrylic resin, an epoxy resin, polyimide, polyethylene, or silicon oxycarbon (SiOC) and be formed of an organic insulating material. For example, the organic encapsulation layer PCL may be formed through an inkjet scheme.

The second inorganic encapsulation layer PAS2 may be formed over the substrate SUB, where the organic encapsulation layer PCL is formed, to cover the upper surface and side surfaces of each of the organic encapsulation layer PCL and the first inorganic encapsulation layer PAS1. The second inorganic encapsulation layer PAS2 may minimize or block penetration of external moisture or oxygen into the first inorganic encapsulation layer PAS1 and the organic encapsulation layer PCL. For example, the second encapsulation layer PAS2 is formed of an inorganic insulating material, such as silicon nitride (SiNx), silicon oxide (SiOx), silicon oxynitride (SiON), or aluminum oxide (Al2O3).

Referring to FIG. 4, when the touch sensor TS is of a type embedded in the display panel PNL, the touch sensor TS may be disposed on the encapsulation layer ENCAP. The touch sensor structure is described below in detail.

A touch buffer film T-BUF may be disposed on the encapsulation layer ENCAP. A touch sensor TS may be disposed on the touch buffer film T-BUF.

The touch sensor TS may include touch sensor metals TSM and a bridge metal BRG positioned on different layers.

A touch interlayer insulation film T-ILD may be disposed between the touch sensor metals TSM and the bridge metal BRG.

For example, the touch sensor metals TSM may include a first touch sensor metal TSM, a second touch sensor metal TSM, and a third touch sensor metal TSM that are disposed adjacent to each other. The third touch sensor metal TSM is disposed between the first touch sensor metal TSM and the second touch sensor metal TSM and, when the first touch sensor metal TSM and the second touch sensor metal TSM are electrically connected to each other, the first touch sensor metal TSM and the second touch sensor metal TSM may be electrically connected to each other through the bridge metal BRG positioned on a different layer. The bridge metal BRG may be insulated from the third touch sensor metal TSM by the touch interlayer insulation film T-ILD.

When the touch sensor TS is formed on the display panel PNL, moisture may be generated from the chemical solution (e.g., developer or etchant) used in the process. By disposing the touch sensor TS on the touch buffer film T-BUF, it is possible to prevent or at least reduce a chemical solution or moisture from penetrating into the light emitting layer EL including an organic material during the manufacturing process of the touch sensor TS. Thus, the touch buffer film T-BUF may prevent damage to the light emitting layer EL vulnerable to chemicals or moisture.

The touch buffer film T-BUF is formed of an organic insulation material with a low permittivity of 1 to 3 and formed at a low temperature which is not more than a predetermined temperature (e.g., 100° C.) to prevent damage to the light emitting layer EL containing the organic material vulnerable to high temperature. For example, the touch buffer film T-BUF may be formed of an acrylic-based, epoxy-based, or siloxane-based material. As the display device 100 is bent, the encapsulation layer ENCAP may be damaged, and the touch sensor metal positioned on the touch buffer layer T-BUF may be broken. Even when the display device 100 is bent, the touch buffer layer T-BUF formed of an organic insulating material and having planarization capability may prevent or at least reduce damage to the encapsulation layer ENCAP and/or breakage of the metals TSM and BRG constituting the touch sensor TS.

A protection layer PAC may be disposed while covering the touch sensor TS. The protective layer PAC may be an organic insulation film.

The display device according to an embodiment may perform touch sensing in the mutual capacitance-based touch sensing scheme or the self-capacitance based touch sensing scheme. In the following example, the display device performs mutual-capacitance-based touch sensing and has a touch sensor structure for the same, for ease of description.

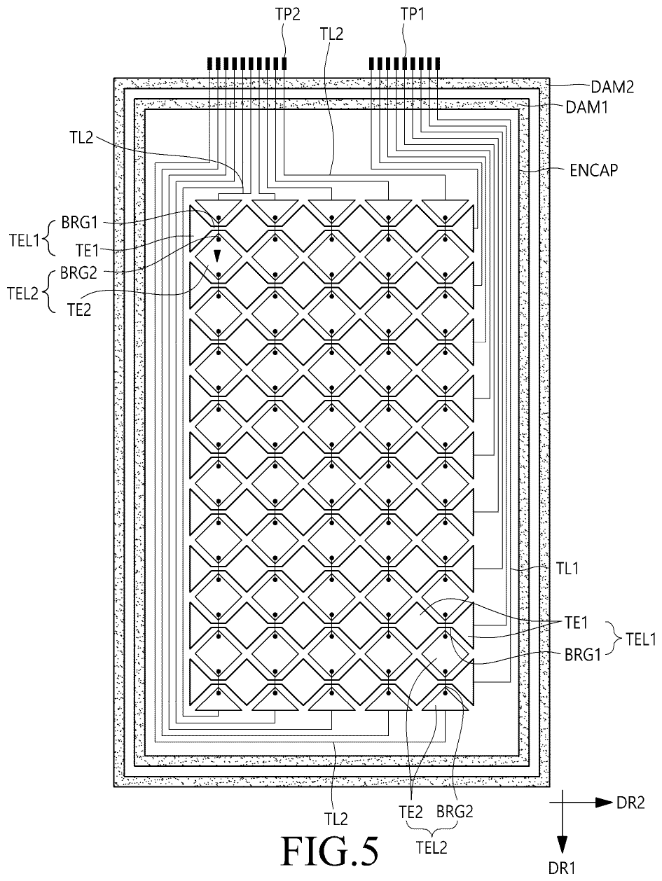

FIG. 5 is a view illustrating components for touch sensing according to embodiments of the disclosure.

Referring to FIG. 5, a touch sensor structure for mutual-capacitance-based touch sensing may include a plurality of first touch electrode lines TEL1 and a plurality of second touch electrode lines TEL2. Here, the plurality of first touch electrode lines X-TEL and the plurality of second touch electrode lines Y-TEL may be positioned on the encapsulation layer ENCAP.

Each of the plurality of first touch electrode lines TEL1 may be disposed in a first direction Direction1, and each of the plurality of second touch electrode lines TEL2 may be disposed in a second direction Direction2. The first direction Direction1 and the second direction Direction2 are directions that cross each other.

Referring to FIG. 5, each of the plurality of first touch electrode lines TEL1 may be composed of a plurality of first touch electrodes TE1 that are electrically connected. Each of the second touch electrode lines TEL2 may be constituted of a plurality of second touch electrodes Y-TE electrically connected with each other. The plurality of first touch electrodes TE1 and the plurality of second touch electrodes TE2 are included in the plurality of touch electrodes TE. The plurality of first touch electrodes TE1 constituting each of the plurality of first touch electrode lines TEL1 may be driving touch electrodes, and the plurality of second touch electrodes TE2 constituting each of the plurality of second touch electrode lines TEL2 may be sensing touch electrodes. In this case, each of the plurality of first touch electrode lines TEL1 corresponds to the driving touch electrode line, and each of the plurality of second touch electrode lines TEL2 corresponds to the sensing touch electrode line.

Referring to FIG. 5, a touch sensor metal for touch sensing may include a plurality of touch routing lines TL as well as the plurality of first touch electrode lines TEL1 and the plurality of second touch electrode lines TEL2. The plurality of touch routing line TL may include one or more first touch routing line TL1 connected to each of the plurality of first touch electrode lines TEL1, and one or more second touch routing line TL2 connected to each of the plurality of second touch electrode lines TEL2.

Referring to FIG. 5, each of the plurality of first touch electrode lines TEL1 may include a plurality of first touch electrodes TE1 disposed in the same row or column, and one or more first bridge metals BRG1 electrically connecting them. Here, the first bridge metal BRG1 connecting the two adjacent first touch electrodes TE1 may be a metal integrated with the two adjacent first touch electrodes TE1 or may also be a metal connected to the two adjacent first touch electrodes TE1 through a contact hole.

Each of the plurality of second touch electrode lines TEL2 may include a plurality of second touch electrodes TE2 disposed in the same column or row, and one or more second bridge metals BRG2 electrically connecting them. Here, the second bridge metal BRG2 connecting the two adjacent second touch electrodes TE2 may be a metal integrated with the two adjacent second touch electrodes TE2 or may also be a metal connected to the two adjacent second touch electrodes TE2 through a contact hole.

Here, the first bridge metal BRG1 or the second bridge metal BRG2 connected to the first touch electrode TE1 or the second touch electrode TE2 through the contact hole may be referred to as a “connection pattern”.

In an area (a touch electrode line crossing area) where the first touch electrode line TEL1 and the second touch electrode line TEL2 cross each other, the first bridge metal BRG1 and the second bridge metal BRG2 may cross each other.

As described above, when the first bridge metal BRG1 and the second bridge metal BRG2 cross each other in the touch electrode line crossing area, the first bridge metal BRG1 and the second bridge metal BRG2 may be disposed in different layers.

Therefore, in order to cross the plurality of first touch electrode lines TEL1 and the plurality of second touch electrode lines TEL2, the plurality of first touch electrodes TE1, the plurality of first bridge metals BRG2, the plurality of second touch electrode lines TEL2, and the plurality of second bridge metals BRG2 may be disposed in two or more layers.

Referring to FIG. 5, each of the plurality of first touch electrode lines TEL1 is electrically connected to the corresponding first touch pad TP1 through one or more first touch routing lines TL1. In other words, the first touch electrode TE1 disposed on the outermost side among the plurality of first touch electrodes TE1 included in the one first touch electrode line TEL1 is electrically connected to the corresponding first touch pad TP1 through the first touch routing line TL1.

Each of the plurality of second touch electrode lines TEL2 is electrically connected to the corresponding second touch pad TP2 through one or more second touch routing lines TL2. In other words, the second touch electrode TE2 disposed on the outermost side among the plurality of second touch electrodes TE2 included in one second touch electrode line TEL2 is electrically connected to the corresponding second touch pad TP2 through the second touch routing line TL2. Hereinafter, wires or lines electrically connected to the touch pads TP1 and TP2 are described in more detail.

FIG. 6 is a view illustrating a touch routing line TL1s of a non-display area NDA according to embodiments of the disclosure.

Referring to FIG. 6, the substrate 111 illustrated in FIG. 6 may be the same as the substrate 111 illustrated in FIG. 3. Among the components of the substrate 111 illustrated in FIG. 6, descriptions of the same components as those of the substrate 111 illustrated in FIG. 3 may be omitted.

The cathode electrode CE may be disposed on the substrate 111. The common electrode CE may overlap the display area DA. The periphery of the cathode electrode CE may be positioned further outside than the periphery of the display area DA. Therefore, referring to FIG. 6, the periphery of the cathode electrode CE is illustrated as including the periphery of the display area DA.

The bending area BA may be positioned between the display area DA and the pad area PA. It may be positioned at the edge of the substrate 111 in the pad area PA. The pad area PA may include a plurality of pads PD. The plurality of pads PD may include a plurality of first touch pads TP1.

The plurality of first touch pads TP1 may be electrically connected to a plurality of first touch routing lines TL1s. The plurality of first touch routing lines TL1s may extend from the pad area PA to the bending area BA. The plurality of first touch routing lines TL1s may extend through the bending area BA to the periphery of the display area DA. The plurality of first touch routing lines TL1s may be disposed to surround the periphery of the display area DA.

The plurality of first touch routing lines TLis may include an outer touch routing line TL1_a and an inner touch routing line TL1_b.

The inner touch routing line TL1_b may be positioned closer to the display area DA than the outer touch routing line TL1_a. The outer touch routing line TL1_a may be disposed outside the inner touch routing line TL1_b. The outer touch routing line TL1_a may be disposed at the outermost one among the plurality of first touch routing lines TL1s.

Since the inner touch routing line TL1_b and the outer touch routing line TL1_a are disposed at different positions, the length of the inner touch routing line TL1_b may be different from the length of the outer touch routing line TL1_a. Due to the above-described length difference, the transmission time of the signal supplied to the inner touch routing line TL1_b may be different from the transmission time of the signal supplied to the outer touch routing line TL1_a. This may be an RC delay. The RC delay is an indicator of the time when a signal is transmitted. The RC delay is proportional to resistance and capacitance, and the magnitude of resistance is proportional to the length of the resistance element. As the length of the resistance element increases, the resistance increases and, as the resistance increases, the RC delay value increases. Accordingly, a difference may occur in the signal transmission time between the lines TL1_a and TL1_b.

In order to prevent the above-described phenomenon, the outer touch routing line TL1_a may include a pattern that is not bent in the first pattern area 610. The inner touch routing line TL1_b may include a pattern bent in the second pattern area 620. Since the inner touch routing line TL1_b includes a bent pattern, the length of the inner touch routing line TL1_b may be longer. Accordingly, the difference between the length of the outer touch routing line TL1_a and the length of the inner touch routing line TL1_b may be decreased. Accordingly, a difference in transmission time between signals supplied to the outer touch routing line TL1_a and the inner touch routing line TL1_b, respectively, may be decreased.

Meanwhile, referring to FIG. 6, area A-B, area C-D, and area E-F may be identified. Hereinafter, area A-B, area C-D, and area E-F are described. Hereinafter, only the plurality of first touch routing lines TL1s are described for convenience of description, but characteristics applied to the plurality of first touch routing lines TL1s may also be applied to a plurality of second touch routing lines TL2s.

FIGS. 7, 8, 9, and 10 are cross-sectional views of area A-B illustrated in FIG. 6 according to embodiments of the present disclosure.

Some components ILD2, PLN1, PLN2, CE, PAS1, PCL, PAS2, and T-ILD illustrated in FIGS. 7 to 10 may include the same characteristics as some components ILD2, PLN1, PLN2, CE, PAS1, PCL, PAS2, and T-ILD illustrated in FIG. 4. Among the components illustrated in FIGS. 7 to 10, descriptions of the same components as those illustrated in FIG. 4 may be omitted.

Referring to FIG. 7, the driving voltage line VDDL may include a first source drain electrode pattern material portion SD1 and a second source drain electrode pattern material portion SD2. The first source drain electrode pattern material portion SD1 of the driving voltage line VDDL may be electrically connected to the second source drain electrode pattern material portion SD2 of the driving voltage line VDDL.

Referring to FIG. 7, the base voltage line VSSL may include a first source drain electrode pattern material portion SD1 and a second source drain electrode pattern material portion SD2. The first source drain electrode pattern material portion SD1 of the base voltage line VSSL may be electrically connected to the second source drain electrode pattern material portion SD2 of the base voltage line VSSL.

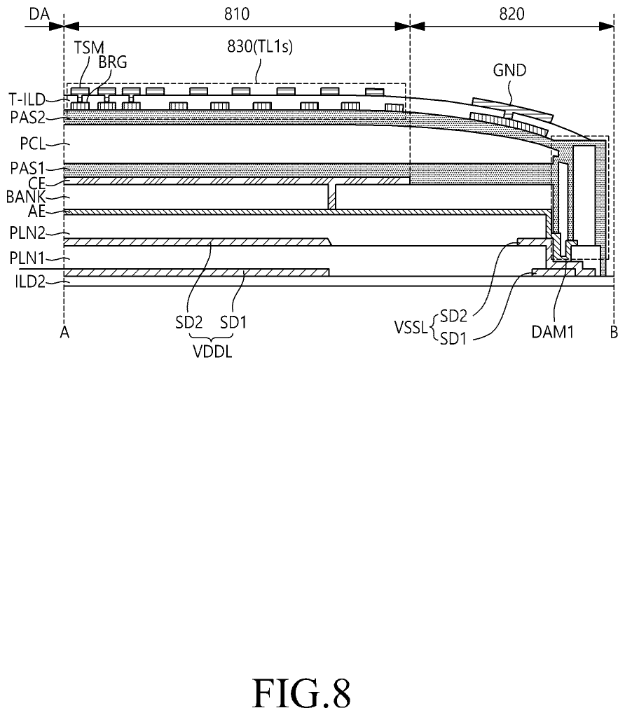

Referring to FIG. 7, the cathode electrode CE may be disposed on the second planarization layer PLN2. The cathode electrode CE may be electrically connected to the base voltage line VSSL. Referring to FIG. 7, an electrical connection portion EC to which the cathode CE and the base voltage line VSSL are electrically connected may be identified. This is described in greater detail with reference to FIG. 8. Referring to FIG. 8, the cathode electrode CE may be electrically connected to the anode electrode AE, and the anode electrode AE may be electrically connected to the base voltage line VSSL.

Referring to FIG. 7, a planar area 710 and an inclined area 720 may be identified. The planar area 710 may be an area in which the encapsulation layer PCL is flat. Alternatively, the planar area 710 may correspond to a position where the cathode electrode CE is disposed. The inclined area 720 may be an area in which the height of the encapsulation layer PCL decreases toward the outside of the substrate 111.

The plurality of first touch routing lines 730 and TL1s may be disposed on the planar area 710. The plurality of first touch routing lines 730 and TL1s may be in the form of a single line. A portion of the plurality of first touch routing lines 730 and TL1s may include a material of the touch sensor metal TSM, and another portion of the plurality of first touch routing lines 730 and TL1s may include a material of the bridge metal BRG.

Referring to FIG. 7, the ground metal GND may be disposed on the inclined area 720. The ground metal GND may be a metal for supplying a ground voltage. The ground metal GND may include a bridge metal material portion BRG and a touch sensor metal material portion TSM. The bridge metal material portion BRG of the ground metal GND may be electrically connected to the touch sensor metal material portion TSM of the ground metal GND.

Referring to FIG. 8, the plurality of first touch routing lines 830, TL1s may be disposed in the planar area 810, and the ground metal GND may be disposed in the inclined area 820. The encapsulation layer PCL may be disposed adjacent to the first dam DAM1 disposed outside the encapsulation layer PCL in the inclined area 820. The first dam DAM1 may include a material of a bank BANK. The first dam DAM1 may include one or more dam shapes. Referring to FIG. 8, the first dam DAM1 includes two dam shapes.

Meanwhile, the planar area 810 and the inclined area 820 are included in the non-display area NDA. One development direction for the display device 100 may involve reducing the area of the non-display area NDA. In order to reduce the area of the non-display area NDA, the components disposed in the planar area 810 and the inclined area 820 may be more densely disposed.

For example, referring to FIG. 8, only the ground metal GND is disposed in the inclined area 820. When only the ground metal GND is disposed in the inclined area 820, the ground metal GND may be easily designed. However, when not only the ground metal GND but also other components are disposed in the inclined area 820, the area of the non-display area NDA may be decreased.

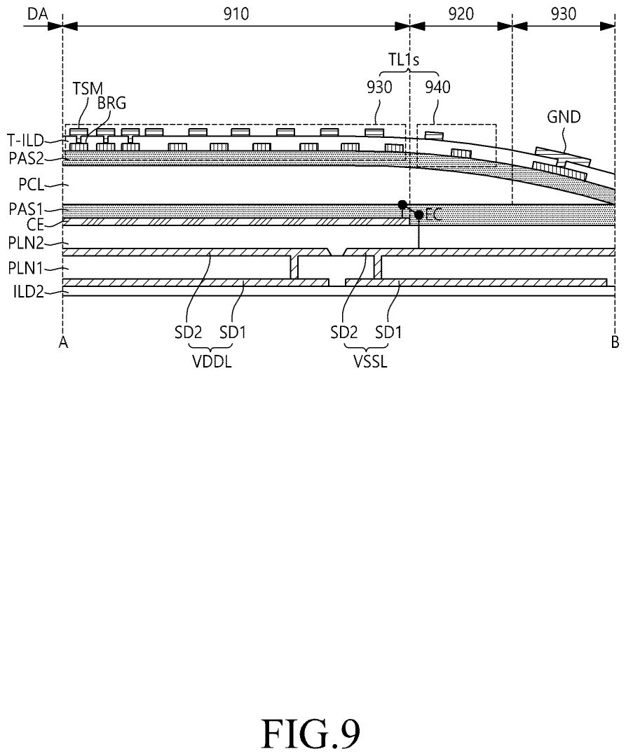

In other words, the narrow bezel may be achieved more easily. The narrow bezel refers to a state in which the area of the non-display area NDA is relatively decreased. Referring to FIG. 9, an example for narrow bezel may be identified.

Referring to FIG. 9, unlike the illustration in FIG. 8, the first inclined area 920 and the second inclined area 930 may be positioned outside the planar area 910. In other words, the inclined area 820 illustrated in FIG. 8 may be divided into the first inclined area 920 and the second inclined area 930 illustrated in FIG. 9. The inclined area 820 illustrated in FIG. 8 may be divided into the first inclined area 920 and the second inclined area 930, and components may be disposed to be spaced apart from each other in the divided areas 920 and 930.

Referring to FIG. 9, the first inclined area 920 may be positioned outside the planar area 910. The second inclined area 930 may be positioned outside the first inclined area 920. The second inclined area 930 may be an area extending from the first inclined area 920. The slope of the second inclined area 930 may be larger than that of the first inclined area 920. The horizontal width of the first inclined area 920 may be the same as the horizontal width of the second inclined area 930, but the disclosure is not limited thereto. In other words, in order to design a narrow bezel, the horizontal width of the first inclined area 920 may be different from the horizontal width of the second inclined area 930.

Referring to FIG. 9, a portion of the first touch routing lines 930, TL1s may be disposed in the planar area 910. Further, another portion of the first touch routing lines 930, TL1s may be disposed in the first inclined area 920.

Referring to FIG. 9, the ground metal GND may be disposed in the second inclined area 930, and the ground metal GND may not be disposed in the first inclined area 920. Instead of the ground metal GND not being disposed in the first inclined area 920, a portion of the first touch routing lines 930, TL1s may be disposed in the first inclined area 920. Since a portion of the first touch routing lines 930, TL1s is disposed in the first inclined area 920, the area in which the first touch routing lines 930, TL1s disposed in the planar area 910 are positioned may be more densely designed. Accordingly, it is possible to design a narrow bezel more easily.

For example, the number of first touch routing lines TL1s may be n. Referring to FIG. 9, two first touch routing lines TL1s are disposed in the first inclined area 920. In this case, since the two first touch routing lines TL1s are disposed in the first inclined area 920, the remaining n−2 first touch routing lines TL1s are disposed in the planar area 910. If the first touch routing line TL1s is not disposed in the inclined area 820 as illustrated in FIG. 8, the planar area 810 is inevitably widened. In other words, by disposing the touch routing line TL1s in the first inclined area 920, the narrow bezel may be designed more easily.

Referring to FIG. 9, a first touch routing line TL1s is disposed in the first inclined area 920. However, according to the design, a portion of the first touch routing lines 940 may be disposed in the second inclined area 930, and the ground metal GND may be disposed in the first inclined area 920.

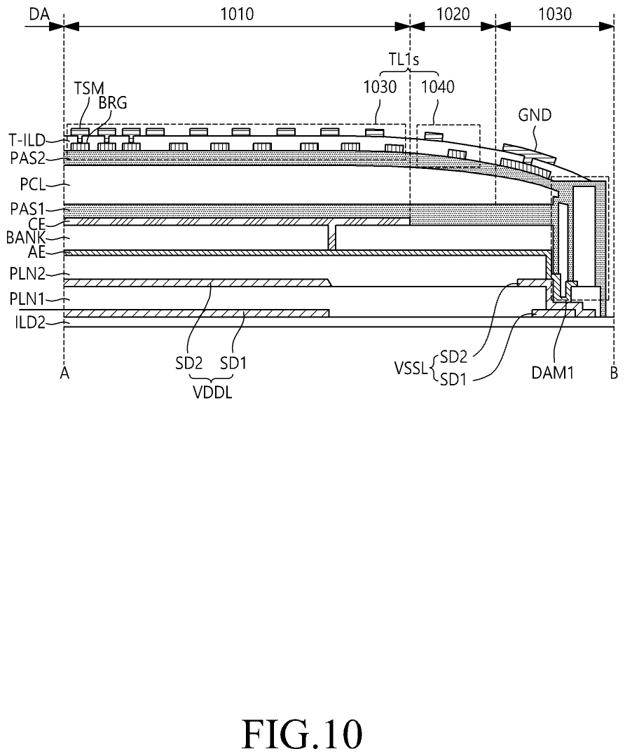

Referring to FIG. 10, a plurality of first touch routing lines 1030, TL1s may be disposed in the planar area 1010 and the first inclined area 1020. A ground metal GND may be disposed in the second inclined area 1030. Referring to FIG. 10, the cathode electrode CE may be electrically connected to the anode electrode AE, and the anode electrode AE may be electrically connected to the base voltage line VSSL. The first dam DAM1 may be disposed outside the encapsulation layer PCL in the second inclined area 1030.

Meanwhile, referring to FIG. 9, the cathode electrode CE may be disposed on the second planarization layer PLN2. Referring to FIG. 9, the cathode electrode CE may be disposed in contact with the second planarization layer PLN2. The cathode electrode CE may receive a voltage from the base voltage line VSSL. In other words, the cathode electrode CE may be electrically connected to the base voltage line VSSL through the electrical connection portion EC. For example, although not illustrated in the cross-sectional view of FIG. 9, the cathode electrode CE may be electrically connected to the base voltage line VSSL through a contact hole formed in the second planarization layer PLN2. The electrical connection portion EC illustrated in FIG. 9 indicates that the cathode electrode CE and the base voltage line VSSL may be electrically connected to each other. Next, an example in which the cathode electrode CE and the base voltage line VSSL are electrically connected is further described with reference to FIG. 10.

Referring to FIG. 10, the anode electrode AE may be disposed on the second planarization layer PLN2. The anode electrode AE may extend in a direction from the display area DA toward the second inclined area 1030. The anode electrode AE may extend through a lower portion of the first inclined area 1020 to a lower portion of the second inclined area 1030. The anode electrode AE may be electrically connected to the base voltage line VSSL in a lower portion of the second inclined area 1030. In the lower portion of the second inclined area 1030, the anode electrode AE may descend along the side surface of the second planarization layer PLN2. Thereafter, the anode electrode AE may be electrically connected to the base voltage line VSSL disposed on the side surface of the first planarization layer PLN1. The base voltage line VSSL is disposed on a side surface of the first planarization layer PLN1, and an end of the base voltage line VSSL may extend between an end of the first planarization layer PLN1 and an end of the second planarization layer PLN2. The bank may be disposed on the anode electrode AE. A contact hole may be formed in the bank, and the cathode electrode CE may be electrically connected to the anode electrode AN through the contact hole. The cathode electrode CE may extend in a direction from the display area DA toward the first inclined area 1020. The cathode electrode CE may be disposed in a lower area of the planar area 1010 and may be electrically connected to the anode electrode AN in the lower portion of the planar area 1010.

Embodiments for area A-B have been described. Area C-D is now described.

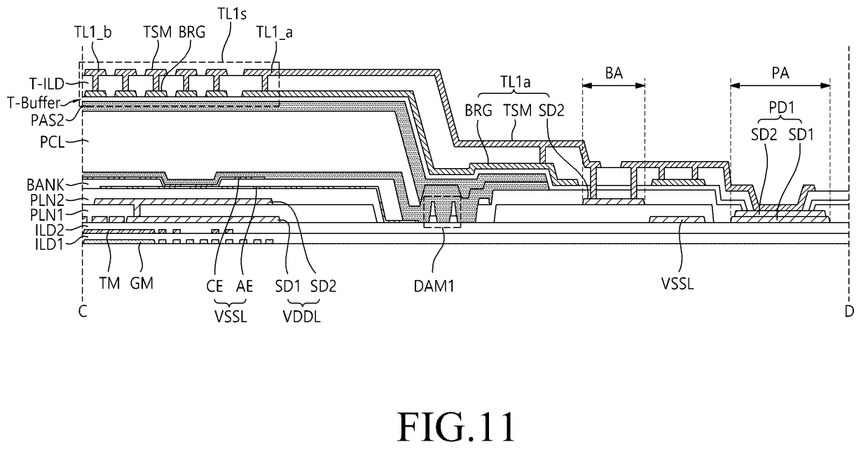

FIG. 11 is a cross-sectional view of area C-D illustrated in FIG. 6 according to one embodiment.

The first touch pad TP1 may be disposed in the pad area PA. The first touch pad TP1 may include a first source drain electrode pattern material portion SD1 and a second source drain electrode pattern material portion SD2. The first source drain electrode pattern material portion SD1 of the first touch pad TP1 may overlap the second source drain electrode pattern material portion SD2 of the first touch pad TP1.

The first touch routing line TL1s may be electrically connected to the first touch pad TP1 in the pad area PA. The first touch routing line TL1s may include a material of the touch sensor metal TSM.

The first touch routing line TL1s may extend from the pad area PA to the display area DA. The first touch routing line TL1s may be in the form of a single line in the pad area PA and may be in the form of a double line when extending to the bending area BA. In this case, the first touch routing line TL1s may include a material of the touch sensor metal TSM and a material of the bridge metal BRG. The touch sensor metal material portion TSM of the ground metal GND may be connected to the bridge metal material portion BRG of the ground metal GND through one or more contact holes.

The first touch routing line TL1s may pass through the bending area BA. The first touch routing line TL1s may be in the form of a single line. In this case, the first touch routing line TL1s may include a material of the touch sensor metal and a second source drain electrode pattern material portion SD2. The touch sensor metal material portion TSM of the ground metal GND may be disposed on the second source drain electrode pattern material portion SD2 of the ground metal GND. The touch sensor metal material portion TSM of the ground metal GND is disposed at two opposite end portions of the bending area BA, and the second source drain electrode pattern material portion SD2 may be disposed in the bending area BA except for the corresponding portion. Accordingly, the first touch routing line TL1s may be disposed in a “U” shape in the bending area BA.

The first touch routing line TL1s may extend from the bending area BA to the display area DA. In this case, the first touch routing line TL1s may be in the form of a double line. The first touch routing line TL1s may include a material of the touch sensor metal TSM and a material of the bridge metal BRG. The first touch routing line TL1s may be disposed to ascend along the inclined surface of the encapsulation layer PCL. Further, the first touch routing line TL1s may extend to a flat surface on the encapsulation layer PCL. The plurality of first touch routing lines TL1s may be positioned on the flat surface on the encapsulation layer PCL.

Referring to FIG. 11, the inner touch routing line TL1_b and the outer touch routing line TL1_a may be identified. It is illustrated that there are six first touch routing lines TL1s, for convenience of description. The number of the plurality of first touch routing lines TL1s is not limited to six.

Referring to FIG. 11, a first dam DAM1 may be positioned outside the encapsulation layer PCL. The first touch routing line TL1s may be disposed on the first dam DAM1. The first dam DAM1 may include one or more dam shapes.

Referring to FIG. 11, the base voltage line VSSL may include a material of a cathode electrode CE and a material of an anode electrode AE. The anode electrode material portion AE of the base voltage line VSSL may be disposed inside the first dam DAM1 and may extend to the display area DA. The anode electrode material portion AE of the base voltage line VSSL may be electrically connected to the cathode electrode material portion CE of the base voltage line VSSL.

A driving voltage line VDDL may be disposed in a lower portion of the area where the cathode electrode CE and the anode electrode AE overlap. The driving voltage line VDDL may include a first source drain electrode pattern material portion SD1 and a second source drain electrode pattern material portion SD2.

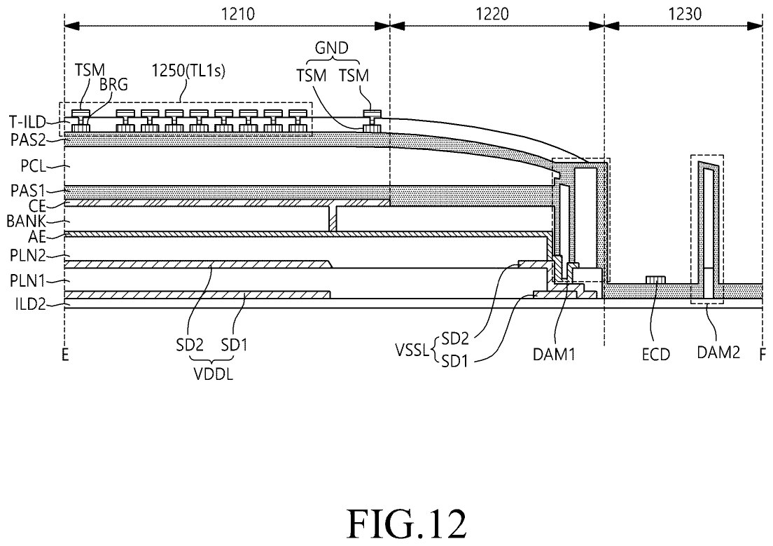

FIGS. 12, 13, and 14 are cross-sectional views of area E-F of FIG. 6 according to embodiments of the present disclosure.

Referring to FIGS. 12, 13, and 14, various embodiments of the ground metal GND may be identified.

Referring to FIG. 12, the plurality of first touch routing lines TL1s may be disposed in the planar area 1210.

Referring to FIG. 12, the ground metal GND may be disposed in the planar area 1210. The ground metal GND may be disposed outside the plurality of first touch routing lines TL1s.

Referring to FIG. 12, the ground metal GND and the plurality of first touch routing lines TL1s may not be disposed in the inclined area 1220.

Referring to FIG. 12, the inclined area 1220 may be defined as a first dam disposed area 1220 as the first dam DAM1 is disposed therein.

Referring to FIG. 12, a second dam disposed area 1230 may be positioned outside the first dam disposed area 1220.

Referring to FIG. 12, a second dam DAM2 may be disposed in the second dam disposed area 1230. The second dam DAM2 may be a component for preventing flooding of an organic layer (e.g., the protective layer PAC of FIG. 4) disposed on the touch sensor metal TSM.

Referring to FIG. 12, an encapsulation layer crack detection portion ECD may be disposed in the second dam disposed area 1230. The encapsulation layer crack detection portion ECD may detect cracks generated in the encapsulation layer PCL. The encapsulation layer crack detection portion ECD may include a material of a bridge metal BRG. The encapsulation layer crack detection portion ECD may be positioned between the first dam DAM1 and the second dam DAM2.

Referring to FIG. 12, it may be identified that the ground metal GND or the first touch routing line TL1s are not disposed in the inclined area 1220. If the ground metal GND or the first touch routing line TL1s is disposed in the inclined area 1220, the narrow bezel may be designed more easily.

Referring to FIG. 12, it may be identified that the ground metal GND or the first touch routing line TL1s is not disposed in the second dam disposed area 1230. If the ground metal GND or the first touch routing line TL1s is disposed in the second dam disposed area 1230, the narrow bezel may be designed more easily.

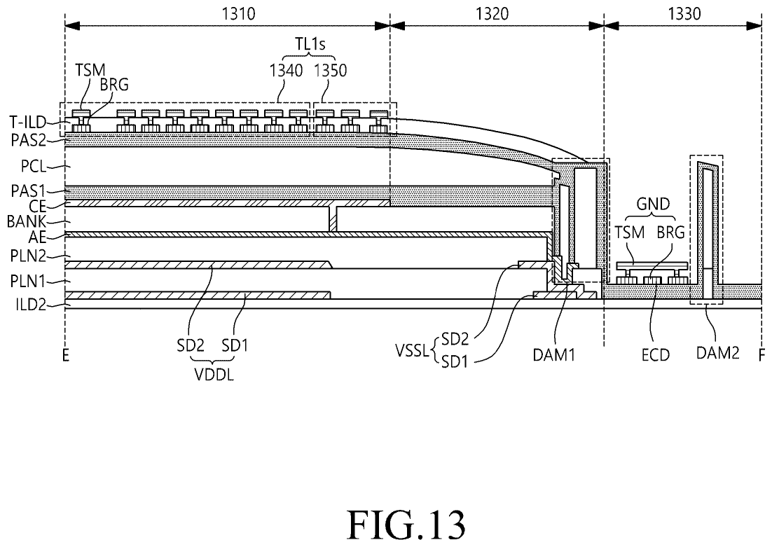

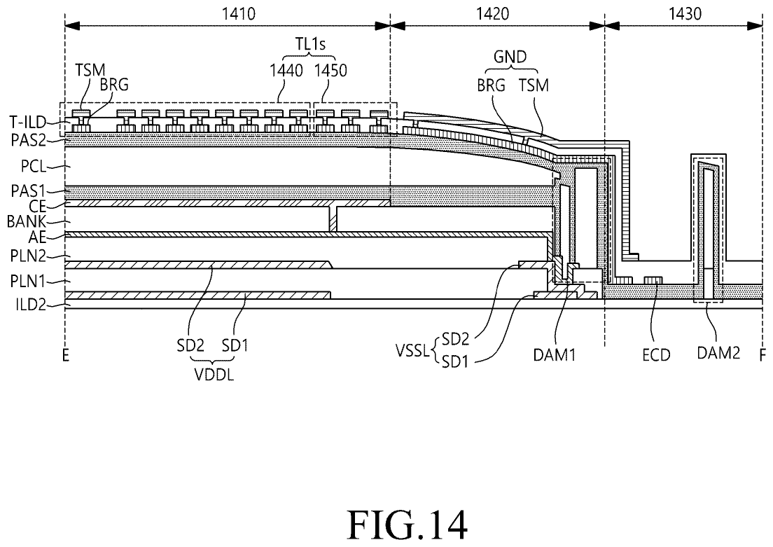

FIG. 13 illustrates an example in which the ground metal GND is disposed in the second dam disposed area 1330, and FIG. 14 illustrates an example in which the ground metal GND is disposed in the inclined area 1420. This is described below with reference to FIGS. 13 and 14.

Referring to FIG. 13, the ground metal GND may be positioned in the second dam disposed area 1330, not the planar area 1310. In this case, while a portion of the plurality of first touch routing lines TL1s is still positioned in the planar area 1310, another portion of the plurality of first touch routing lines TL1s may be disposed in the place where the ground metal GND was disposed. In other words, as the ground metal GND is not disposed in the planar area 1310, the arrangement of the plurality of first touch routing lines TL1s may be freely designed. Accordingly, the size of the bezel may be further decreased.

For example, a portion 1350 of the first touch routing lines TL1s illustrated in FIG. 13 may be positioned in the place of the ground metal GND illustrated in FIG. 12. It may be assumed that the number of first touch routing lines TL1s is n, and the portion 1350 of the first touch routing lines TL1s corresponds to three first touch routing lines TL1s. In this case, the remaining portion 1340 of the first touch routing lines TL1s is n−3 first touch routing lines TL1s, and the area in which the first touch routing lines TL1s are disposed in the planar area 1310 may be further decreased.

Referring to FIG. 13, the ground metal GND may include a material of the bridge metal BRG and a material of the touch sensor metal TSM. The ground metal GND may include two or more metals including the material of the bridge metal BRG, and the encapsulation layer crack detection portion ECD may be positioned therebetween.

Referring to FIG. 13, the ground metal GND may not be disposed in the inclined area 1320. In contrast, referring to FIG. 14, the ground metal GND may be disposed in the inclined area 1420. The inclined areas 1320 and 1420 may be defined as first dam disposed areas 1320 and 1420.

Referring to FIG. 14, the arrangement of the plurality of first touch routing lines TL1s illustrated in FIG. 14 may be the same as the arrangement of the plurality of first touch routing lines TL1s illustrated in FIG. 13. However, there is a difference in the position of the ground metal GND.

Referring to FIG. 14, the ground metal GND may be positioned in the inclined area 1420 and may extend to the second dam disposed area 1430. The ground metal GND may include a material of the bridge metal BRG and a material of the touch sensor metal TSM. The bridge metal material portion BRG of the ground metal GND may extend from the inclined area 420 to the second dam disposed area 1430 and may pass over the first dam DAM1.

The touch sensor metal material portion TSM of the ground metal GND may extend from the inclined area 720 to the second dam disposed area 1430. The touch sensor metal material portion TSM of the ground metal GND may be electrically connected to the bridge metal material portion BRG of the ground metal GND.

The position of the encapsulation layer crack detection portion ECD illustrated in FIG. 14 may be the same as the position of the encapsulation layer crack detection portion ECD illustrated in FIG. 12. The encapsulation crack detection portion may not overlap the ground metal GND, but the disclosure is not limited thereto. Depending on the design purpose, the encapsulation crack detection portion may or may not overlap the ground metal GND.

In other words, the narrow bezel may be designed more easily by disposing the position of the ground metal GND illustrated in FIG. 12 in an area other than the planar area 1210. For example, the ground metal GND may be positioned in the second dam disposed area 1320 illustrated in FIG. 13. Further, the ground metal GND may be positioned on the inclined area 1420 illustrated in FIG. 14.

Referring to FIG. 13, it may be identified that the ground metal GND is positioned in the second dam disposed area 1320, and the first touch routing line TL1s is not disposed in the inclined area 1320. In this case, when the first touch routing line TL1s is disposed in the inclined area 1320, the narrow bezel may be designed to be thinner.

Referring to FIG. 14, it may be identified that the ground metal GND is disposed in the inclined area 1420. In this case, the ground metal GND may be designed to be offset toward the lower portion of the inclined area 1420, and in this case, the first touch routing line TL1s may be designed in the upper portion of the inclined area 1420. Accordingly, it is possible to design a much thinner narrow bezel.

Embodiments of the disclosure described above are briefly described below.

Embodiments of the disclosure may provide a display device comprising a substrate including a display area and a non-display area outside the display area, the non-display area including a pad area and a bending area, a plurality of light emitting elements disposed on the substrate, an encapsulation layer disposed on the plurality of light emitting elements, and a plurality of touch routing lines disposed on an inclined area of the encapsulation layer.

The plurality of touch routing lines may include a first metal pattern material disposed on the encapsulation layer, or a second metal pattern material disposed on the first metal pattern material.

The display device may further comprise a ground metal positioned in the inclined area and disposed outside the touch routing lines.

The plurality of touch routing lines may be disposed in the inclined area and a planar area of the encapsulation layer.

The plurality of touch routing lines may include an inner routing line including a bent pattern, and an outer routing line not including the bent pattern.

The bent pattern may be positioned between the pad area and the bending area.

The inner routing line and the outer routing line may extend in parallel in a direction from the bending area to the display area.

The plurality of light emitting elements may include an anode electrode, a light emitting element intermediate layer on the anode electrode, and a cathode electrode disposed on the light emitting element intermediate layer. The cathode electrode may be electrically connected to a base voltage line. The base voltage line may include a first source drain electrode pattern disposed on the substrate, a second source drain electrode pattern electrically connected to the first source drain electrode pattern, an anode metal pattern electrically connected to the second source drain electrode pattern and including a material included in the anode electrode, and a cathode metal pattern electrically connected to the anode metal pattern and including a material included in the cathode electrode.

The plurality of touch routing lines may overlap the anode metal pattern in the inclined area. The plurality of touch routing lines may not overlap the cathode metal pattern in the planar area of the encapsulation layer.

The display device may further comprise a driving voltage line including a material included in the first source drain electrode pattern and a material included in the second source drain electrode pattern. The plurality of touch routing lines may not overlap the driving voltage line.

A portion of the plurality of touch routing lines may be a first touch routing line extending in a direction from the display area toward the pad area. At least the portion of the plurality of touch routing lines may include a bridge metal material portion and a touch sensor metal material portion in an area between the display area and the bending area. The first touch routing line may include the touch sensor metal material portion and a source drain metal material portion in the bending area. The first touch routing line may include the bridge metal material portion and the touch sensor metal material portion between the bending area and the pad area. The first touch routing line may include the touch sensor metal material portion in the pad area. The display device may further comprise a first touch pad electrically connected to the first touch routing line.

The first touch pad may include the source drain metal material portion and a metal material different from the source drain metal material portion.

The display device may further comprise a ground metal disposed in the planar area of the encapsulation layer.

The display device may further comprise a ground metal disposed outside the encapsulation layer.

At least a portion of the plurality of touch routing lines may be disposed in the planar area of the encapsulation layer and positioned adjacent to the inclined area.

The display device may further comprise a first dam disposed outside the encapsulation layer, and a second dam disposed outside the first dam. The ground metal may be positioned between the first dam and the second dam.

The display device may further comprise an encapsulation layer crack detection portion disposed to overlap the ground metal.

The display device may further comprise a ground metal extending from the inclined area to an outside of the encapsulation layer.

At least a portion of the plurality of touch routing lines may be disposed in the planar area of the encapsulation layer and positioned adjacent to the ground metal disposed in the inclined area.

Embodiments of the disclosure may provide a display device comprising a substrate, a plurality of light emitting elements disposed on the substrate, an encapsulation layer disposed on the plurality of light emitting elements and including a planar area and an inclined area outside the planar area, an inner touch routing line disposed in the planar area, and an outer touch routing line disposed in the inclined area.

The above description has been presented to enable any person skilled in the art to make and use the technical idea of the disclosure and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed is:

1. A display device comprising:
a substrate including a display area and a non-display area outside the display area;
a plurality of light emitting elements on the substrate;
an encapsulation layer on the plurality of light emitting elements; and
a plurality of touch routing lines on an inclined area of the encapsulation layer.

2. The display device of claim 1, wherein the plurality of touch routing lines include a first metal pattern material on the encapsulation layer or a second metal pattern material on the first metal pattern material.

3. The display device of claim 1, further comprising:
a ground metal in the inclined area and disposed outside the plurality of touch routing lines.

4. The display device of claim 1, wherein the plurality of touch routing lines are in the inclined area and a planar area of the encapsulation layer.

5. The display device of claim 1, wherein the plurality of touch routing lines include:
an inner routing line including a bent pattern; and
an outer routing line that lacks the bent pattern, and
wherein the non-display area includes a pad area and a bending area.

6. The display device of claim 5, wherein the bent pattern is between the pad area and the bending area.

7. The display device of claim 5, wherein the inner routing line and the outer routing line extend in parallel in a direction from the bending area to the display area.

8. The display device of claim 1, wherein the plurality of light emitting elements include an anode electrode, a light emitting element intermediate layer on the anode electrode, and a cathode electrode disposed on the light emitting element intermediate layer,
wherein the cathode electrode is electrically connected to a base voltage line, and
wherein the base voltage line includes:
a first source drain electrode pattern on the substrate;
a second source drain electrode pattern electrically connected to the first source drain electrode pattern;
an anode metal pattern electrically connected to the second source drain electrode pattern, the anode metal pattern including a material included in the anode electrode; and
a cathode metal pattern electrically connected to the anode metal pattern, the cathode metal pattern including a material included in the cathode electrode.

9. The display device of claim 8, wherein the plurality of touch routing lines overlap the anode metal pattern in the inclined area and the plurality of touch routing lines are non-overlapping with the cathode metal pattern in a planar area of the encapsulation layer.

10. The display device of claim 8, further comprising:
a driving voltage line including a material included in the first source drain electrode pattern and a material included in the second source drain electrode pattern,
wherein the plurality of touch routing lines are non-overlapping with the driving voltage line.

11. The display device of claim 1, wherein a portion of the plurality of touch routing lines is a first touch routing line extending in a direction from the display area toward a pad area of the non-display area,
wherein the first touch routing line includes a bridge metal material portion and a touch sensor metal material portion in an area between the display area and a bending area of the non-display area,
wherein the first touch routing line includes the touch sensor metal material portion and a source drain metal material portion in the bending area,
wherein the first touch routing line includes the bridge metal material portion and the touch sensor metal material portion between the bending area and the pad area,
wherein the first touch routing line includes the touch sensor metal material portion in the pad area, and
wherein the display device further comprises a first touch pad electrically connected to the first touch routing line.

12. The display device of claim 11, wherein the first touch pad includes the source drain metal material portion and a metal material different from the source drain metal material portion.

13. The display device of claim 4, further comprising:
a ground metal in the planar area of the encapsulation layer.

14. The display device of claim 4, further comprising:
a ground metal disposed outside the encapsulation layer.

15. The display device of claim 14, wherein at least a portion of the plurality of touch routing lines is in a planar area of the encapsulation layer and positioned adjacent to the inclined area.

16. The display device of claim 14, further comprising:
a first dam disposed outside the encapsulation layer; and
a second dam disposed outside the first dam,
wherein the ground metal is positioned between the first dam and the second dam.

17. The display device of claim 14, further comprising:
an encapsulation layer crack detection portion that overlaps the ground metal.

18. The display device of claim 4, further comprising:
a ground metal extending from the inclined area to an outside of the encapsulation layer.

19. The display device of claim 1, further comprising a touch buffer layer between the encapsulation layer and the plurality of touch routing lines and formed of an organic insulating material.

20. The display device of claim 1, wherein the inclined area of the encapsulation layer is disposed in the non-display area.

21. The display device of claim 20, wherein the plurality of touch routing lines extend from the inclined area to the display area to be electrically connected to a plurality of touch electrodes disposed in the display area.

22. A display device comprising:
a substrate;
a plurality of light emitting elements on the substrate;
an encapsulation layer on the plurality of light emitting elements, the encapsulation layer including a planar area and an inclined area outside the planar area;
an inner touch routing line in the planar area; and
an outer touch routing line in the inclined area.

23. A display device comprising:
a substrate;
a plurality of light emitting elements disposed on the substrate;
an encapsulation layer disposed on the plurality of light emitting elements and including a planar area and an inclined area outside the planar area;
a plurality of touch routing lines disposed on the encapsulation layer; and a ground metal disposed in the inclined area of the encapsulation layer.

24. The display device of claim 23, wherein at least a portion of the plurality of touch routing lines is disposed in the inclined area of the encapsulation layer and adjacent to the ground metal disposed in the inclined area.
